(19) United States
(12) Patent Application Publication
(10) Pub. No.: US 2015/0212744 A1
(43) Pub. Date: Jul. 30, 2015

(54) METHOD AND SYSTEM OF EVICTION STAGE POPULATION OF A FLASH MEMORY CACHE OF A MULTILAYER CACHE SYSTEM

(71) Applicants: Haim Helman, Saratoga, CA (US); Krishna Satyasai Yeddanapudi, Milpitas, CA (US); Gurmeet Singh, Fremont, CA (US)

(72) Inventors: Haim Helman, Saratoga, CA (US); Krishna Satyasai Yeddanapudi, Milpitas, CA (US); Gurmeet Singh, Fremont, CA (US)

(21) Appl. No.: 14/164,248

(22) Filed: Jan. 26, 2014

(51) Int. Cl. G06F 3/06; G06F 12/12; G11C 7/10; G06F 12/08

(52) U.S. Cl. CPC G06F 3/0616; G06F 12/0833; G06F 12/128; G06F 3/0679; G06F 3/0655; G06F 3/0685; G11C 7/1072; G06F 2212/62; G06F 2212/69; G06F 2206/1014

(57) ABSTRACT

In one exemplary aspect, a primary cache is maintained in a main memory of a computer system. The primary cache is populated with a set of data from a secondary data storage system. A secondary cache is maintained in another memory of the computer system. A subset of data is selected from the set of data in the primary cache. A trigger event is detected. The secondary cache is populated with the subset of data selected from the set of data in the primary cache. Optionally, a lifespan of each memory page in the primary cache can be estimated. Memory pages with lifespans within a specified lifespan range can be associated. A set of associated memory pages with lifespans within the specified lifespan range can be written to a block in the flash memory system. The main memory of the computer system can include a dynamic random-access memory (DRAM) memory system. The other memory of the computer system can include a flash memory system in a solid-state storage device.

### BACKGROUND

1. Field

This application relates generally to computer memory management, and more specifically to a system, article of manufacture and method for eviction stage population of a flash memory cache of a multilayer cache system.

2. Related Art

Flash memory can be an electronic non-volatile computer storage medium that can be electrically erased and reprogrammed. While it can be read and/or programmed a byte or a word at a time in a random access fashion, some forms of flash memory can only be erased a unit block at a time. Additionally, some forms of flash memory may have as finite number of program-erase cycle before the wear begins to deteriorate the integrity of the storage.

In some forms of multilayer caching, data may be fetched from lower layers (e.g. a secondary cache) to populate a higher layer (e.g. a primary cache). The lower layer may fetch data from secondary storage (e.g. a hard-disk drive). This model can result in inefficient and/or unnecessarily writes in the flash memory of the secondary cache. These unnecessary writes can prematurely degrade the flash memory of the lower layer caches. There is therefore a need and an opportunity to improve the methods and systems whereby a secondary cache implemented in a flash memory can be populated.

### BRIEF SUMMARY OF THE INVENTION

In one aspect, a primary cache is maintained in a main memory of a computer system. The primary cache is populated with a set of data from a secondary data storage system. A secondary cache is maintained in another memory of the computer system. A subset of data is selected from the set of data in the primary cache. A trigger event is detected. The secondary cache is populated with the subset of data selected from the set of data in the primary cache.

Optionally, a lifespan of each memory page in the primary cache can be estimated. Memory pages with lifespans within a specified lifespan range can be associated. A set of associated memory pages with lifespans within the specified lifespan range can be written to a block in the flash memory system. The main memory of the computer system can include a dynamic random-access memory (DRAM) memory system. The other memory of the computer system can include a flash memory system in a solid-state storage device. The secondary data storage system can include a hard-disk storage system.

### BRIEF DESCRIPTION OF THE DRAWINGS

The present application can be best understood by reference to the following description taken in conjunction with the accompanying figures, in which like parts may be referred to by like numerals.

FIG. 1 depicts, in block diagram format, an example of a computer system implementing eviction stage population of a flash memory cache of a multilayer cache, according to some embodiments.

FIG. 2 illustrates an example process of populating a flash memory cache of a multilayer cache during an eviction process of a primary cache (e.g. in RAM memory), according to some embodiments.

FIG. 3 depicts an example process of migrating memory pages cached in a primary cache to a secondary cache in an SSD device during an eviction stage of the primary cache, according to some embodiments.

FIG. 4 depicts an exemplary process of reducing storage of metadata in a secondary cache stored in a flash memory of an SSD device, according to some embodiments.

FIG. 5 depicts a computing system with a number of components that can be used to perform any of the processes described herein.

FIG. 6 is a block diagram of a sample computing environment that can be utilized to implement some embodiments.

FIG. 7 depicts an example distributed database system (DDBS) that implements the multilayer caching processes provided herein according to some embodiments.

The Figures described above are a representative set, and are not an exhaustive with respect to embodying the invention.

### DETAILED DESCRIPTION

Disclosed are a system, method, and article of setting eviction stage population of a flash memory multilayer cache. The following description is presented to enable a person of ordinary skill in the art to make and use the various embodiments. Descriptions of specific devices, techniques, and applications are provided only as examples. Various modifications to the examples described herein may be readily apparent to those of ordinary skill in the art, and the general principles defined herein may be applied to other examples and applications without departing from the spirit and scope of the various embodiments.

Reference throughout this specification to “one embodiment,” “an embodiment,” “one example,” or similar language means that a particular feature, structure, or characteristic described in connection with the embodiment is included in at least one embodiment of the present invention. Thus, appearances of the phrases “in one embodiment,” “in an embodiment,” and similar language throughout this specification may, but do not necessarily, all refer to the same embodiment.

Furthermore, the described features, structures, or characteristics of the invention may be combined in any suitable manner in one or more embodiments. In the following description, numerous specific details are provided, such as examples of programming software modules, user selections, network transactions, database queries, database structures, hardware modules, hardware circuits, hardware chips, etc., to provide a thorough understanding of embodiments of the invention. One skilled in the relevant art can recognize, however, that the invention may be practiced without one or more of the specific details, or with other methods, components, materials, and so forth. In other instances, well-known structures, materials, or operations are not shown or described in detail to avoid obscuring aspects of the invention.

The schematic flow chart diagrams included herein are generally set forth as logical flow chart diagrams. As such, the depicted order and labeled steps are indicative of one embodiment of the presented method. Other steps and methods ma be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagrams, and they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown.

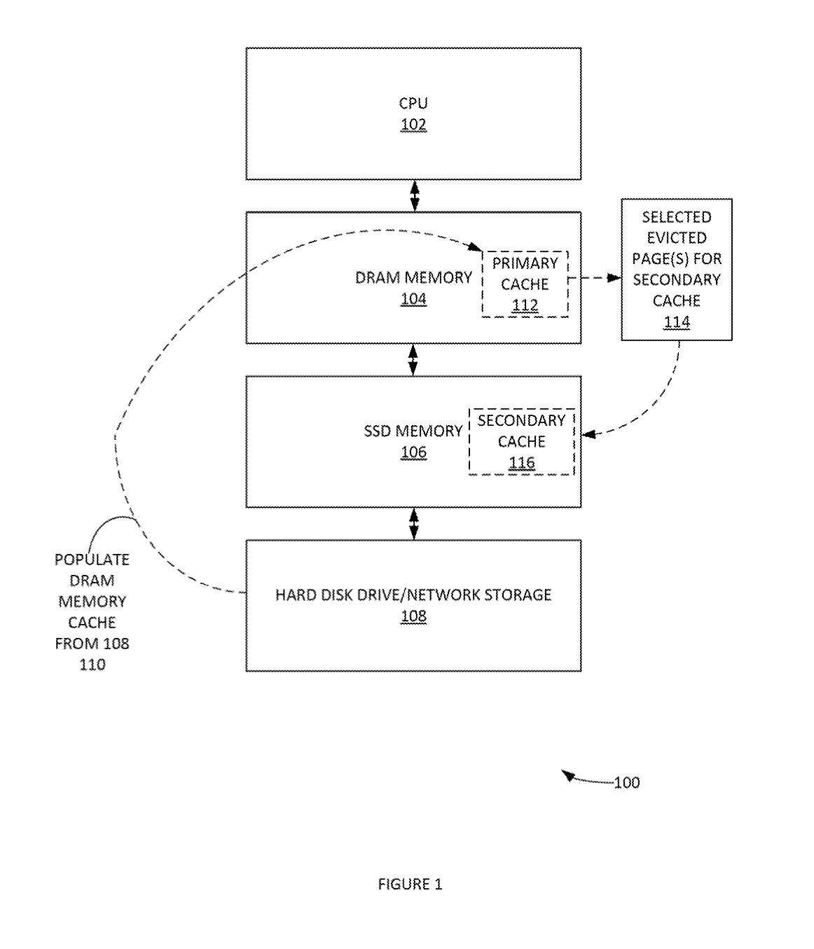

FIG. 1 depicts, in block diagram format, an example of a computer system 100 implementing eviction stage population of a flash memory cache (e.g. a secondary cache) of a multilayer cache, according to some embodiments. In the present example, computer system 100 can include a central processing unit (CPU) 102. CPU 102 can be a hardware within a computer that carries out the instructions of a computer program by performing the basic arithmetical, logical, and input/output operations of the system. CPU 102 can be communicatively coupled with a dynamic random-access memory (DRAM) memory device 104 (and/or other type memory device used to store data or programs on a temporary or permanent basis for use in a computer). DRAM memory 104 can include a primary cache 112 populated with data from a data storage system (e.g. as indicated with step 112) such as a hard disk drive (HDD) and/or remote network storage 108. DRAM memory 104 can be communicatively coupled with to solid-state storage device such flash memory device 106. Additional caches can be stored in various secondary systems such as flash memory device 106 (e.g. secondary cache 116). For example, in step 114, primary cache 112 can be analyzed and various pages thereof selected according to one or more specified metrics (e.g. see infra). Accordingly, in some embodiments, the population phase of secondary cache 116 in the multilayer cache system of computer system 100 can be moved from a fetch stage (e.g. stage when a cache is populated from an HDD) to the eviction stage. As used herein, in some examples, an eviction process can refer to the process by which old, relatively unused, and/or excessively voluminous data can be dropped from the cache, allowing the cache to remain within a memory budget.

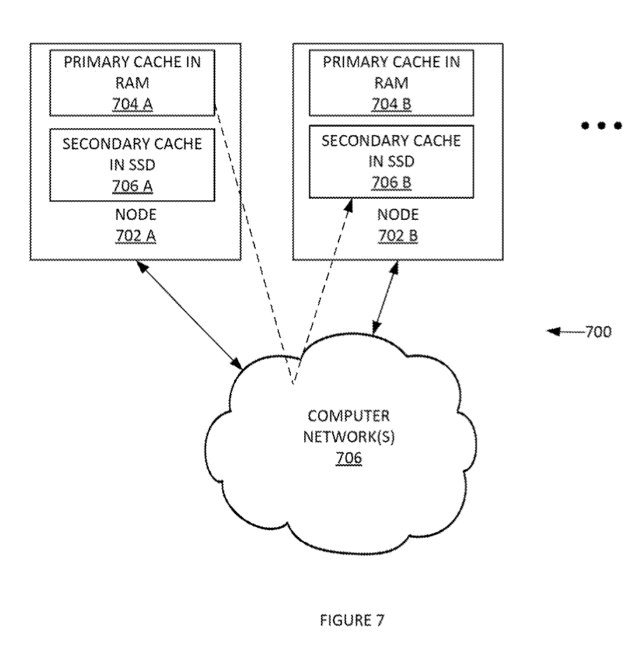

It is further noted, that the system and methods of FIG. 1 are provided by way of example. In another example, two or more secondary caches can be populated by a primary cache in a random access memory. In still another example, one secondary cache can be populated during an eviction stage of a primary cache and another secondary cache can be populated based on other metrics and/or triggers (e.g. based on metric and/or triggers that facilitate a ‘big’ data computing process). It is also noted that the secondary cache can be remote and reside in other nodes of a distributed database cluster (e.g. infra). In some embodiments, system 100 can be implemented in a system with SSD cards in a server to layer virtualization methods. In some embodiments system 100 can be implemented in a system with a remote SSD appliance (e.g. can be remotely accessed via a computer network) that is outside of a server (with the CPU and primary cache) and a storage system (with the hard disk drive). Software in the server can implement the population of the secondary cache store in the remote SSD appliance. Accordingly, system 100 can be implemented in a central (e.g. monolithic) storage environment and/or distributed storage systems (local or remote) (e.g. see FIG. 7). In one example of a remote distributed storage system, the local CPU can view the remote secondary cache's SSD appliance as a backend storage.

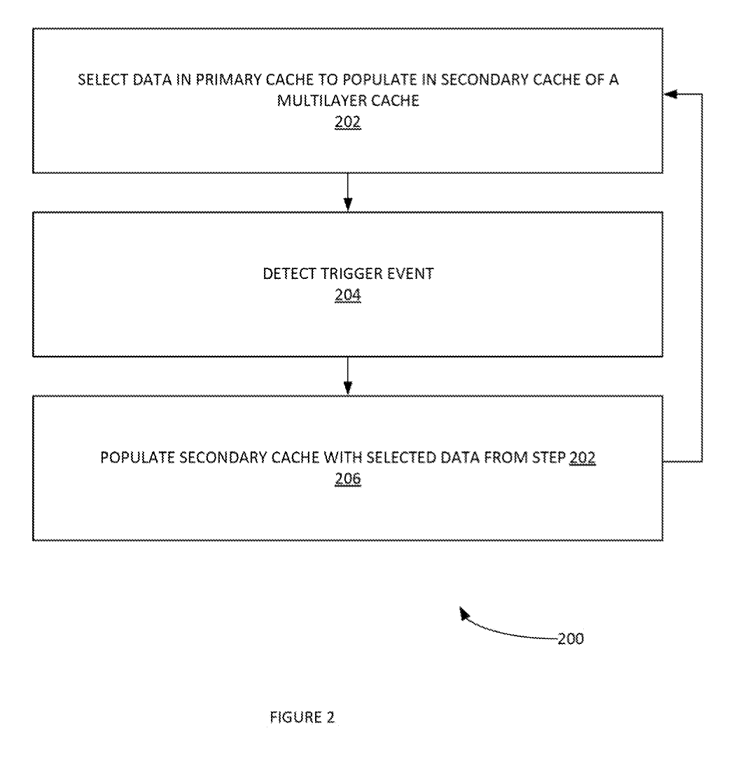

FIG. 2 illustrates an example process 200 of populating a flash memory cache of a multilayer cache during an eviction process of a primary cache (e.g. in RAM memory), according to some embodiments. The flash memory cache can be a secondary cache in a multilayer cache system (e.g. see FIG. 1). In process 200, the population phase of the flash memory cache can occur after the fetch phase of the primary cache from a backend storage (e.g. be triggered by a later eviction operation performed on the primary cache). It is noted, that the primary cache can be populated directly from the second storage device (e.g. skipping a secondary cache in a flash storage device). As used herein, a backend storage device can be a secondary storage system such as a hard disk device and the like. In step 202 of process 200, data in the primary cache of a multilayer cache is selected to populate secondary (or other non-primary cache(s)). This data can be selected based on various metrics such a recency of use by an application, size, a time stamp threshold, an analysis of the history of access to the data, etc. In step 204, a trigger event can be detected. In one example, the trigger event can be an eviction process of data in the primary cache. Upon detection of the trigger event, the data selected in step 202 can be populated to the secondary cache (or other non-primary cache(s)) in step 206. Process 200 can then be repeated. Furthermore, the size of the data sets can be varied based on various factors such as type of computing system, type of data, project type (e.g. ‘big’ data projects can include larger data sets), and the like.

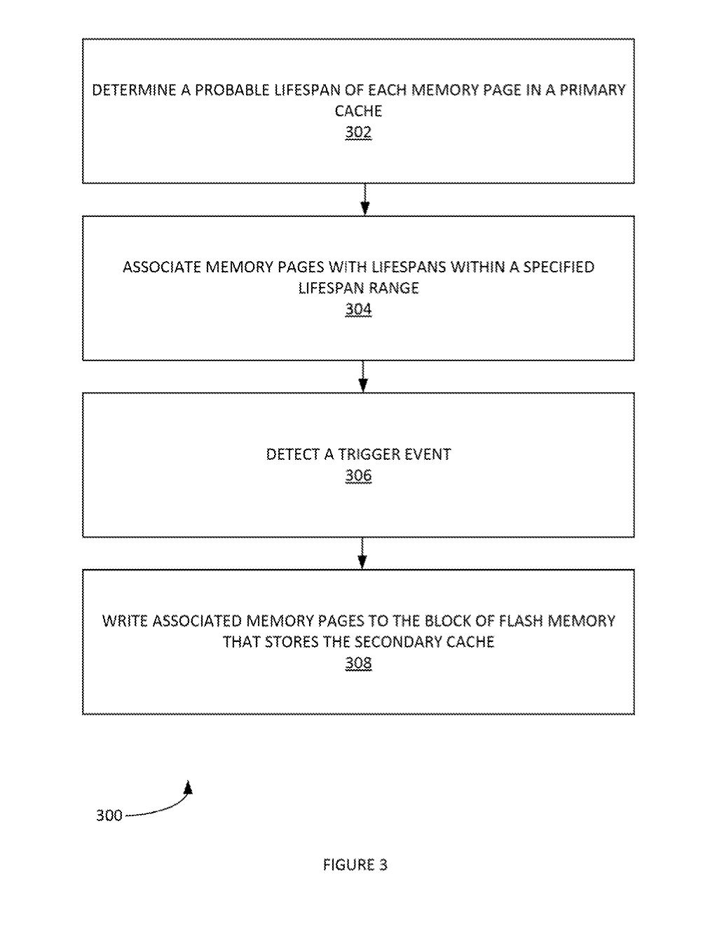

FIG. 3 depicts an example process 300 of migrating memory pages cached in a primary cache to a secondary cache in an SSD device during an eviction stage of the primary cache, according to some embodiments. As used herein, a memory page can be a fixed-length contiguous block of memory (e.g. virtual memory). As used herein, garbage collection (GC) can be a form of automatic memory management. A garbage collector in a memory management module (not shown) can reclaim memory occupied by objects that are no longer in use by the program (i.e. ‘garbage’). During garbage collection in an SSD device data can be written to the flash memory in units of pages. A memory page can be made up of multiple cells of the flash memory. Additionally, the flash memory may be set to be erased in larger units called blocks (e.g. made up of multiple pages). Accordingly, in step 302, a probably lifespan of each memory page in a primary cache can be determined. The probable lifespan can be determined based on such factors as analysis of historical lifespans of other memory pages with similar data, recency of access of the data in the memory pages (e.g. the ‘five-minute rule’), etc. In step 304, various memory pages with lifespans with a specified range can be associated together. The size of this association can be based on the size of the block units of flash memory in the SSD device that stores the secondary cache. In step 306, a trigger event can be detected. In one example, the trigger event can be an eviction process of data in the primary cache. In step 308, associated memory pages can be written to the block of flash memory that stores the secondary cache. In this way, garbage collection processes in the flash memory can be more efficient because each block in more likely to include all and/or greater amounts of valid data and/or memory pages with similar lifetimes.

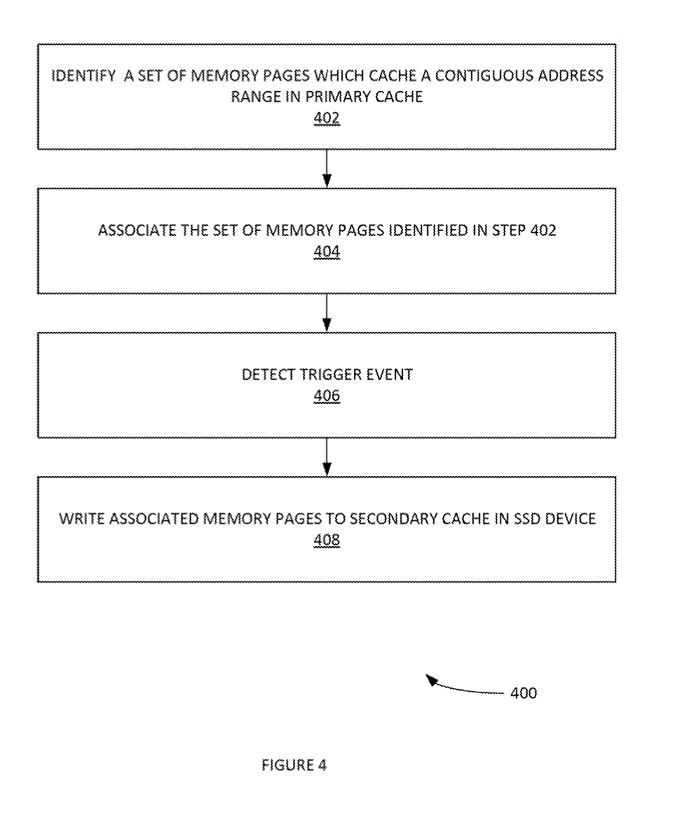

FIG. 4 depicts an exemplary process 400 of reducing storage of metadata in a secondary cache stored in a flash memory of an SSD device, according to some embodiments. In step 402 of process 400, a contiguous memory pages in a primary cache can be identified. In step 404, the contiguous memory pages can be associated (e.g. assigned a common eviction time, associated for migration to a common secondary cache, etc.). In step 406, a trigger event can be detected. In one example, the trigger event can be an eviction process of data in the primary cache. In step 408, the associated contiguous memory pages can be written to a secondary cache in a flash memory of the SSD device. In this way, the grouping of the contiguous memory pages can reduce the amount of metadata about the contiguous memory pages also stored in the secondary cache. In one example, the metadata is the address table becomes be decrease utilized process 400. Memory pages can be store in the primary cache in a DRAM device in four (4) kilobytes groupings and evicted in sixty-four (64) kilobytes grouping as a unit. This 64 kilobytes unit can then be utilized as the page size for secondary cache.

It is noted that data that is accessed sequentially may not be cached in the secondary cache. For example, it can be determine if data sequential in the primary cache is sequential. If yes, then this data may not be stored sequentially in secondary cache. When sequential data is discovered in the secondary cache, the memory pages already in the secondary cache can be overridden and a smaller sample of the data can be retained for sequential access. For example, it is noted that in some embodiments, data that is accessed in a sequential manner may benefit less from long-term caching. Rotating-media hard drives may be better suited to handle sequential access. In this case, a pre-fetch algorithm can be used to detect sequential streams and/or read-ahead the data on demand to reduce read latency. Accordingly, some embodiments can avoid storing sequential data in a secondary cache to avoid unnecessary wear in the solid-state device. Moreover, by delaying the population phase of a secondary (and/or other non-primary cache) cache, the probability of detection of sequential access can be increased. In this way, the amount of sequentially-accessed data being stored in the secondary cache can be decreased.

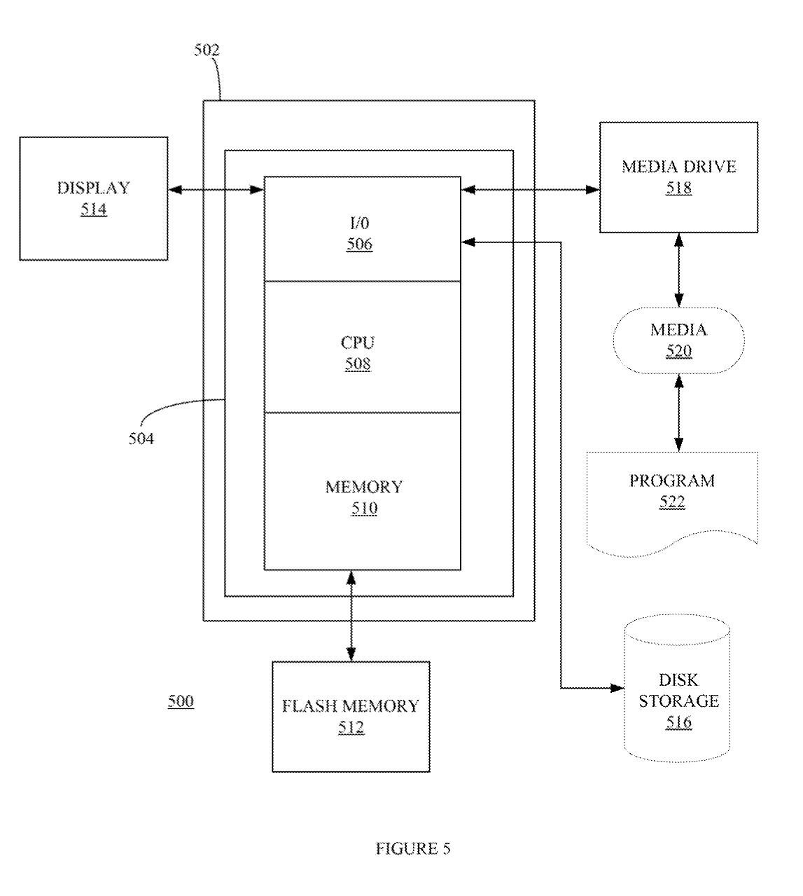

FIG. 5 depicts an exemplary computing system 500 that can be configured to perform several of the processes provided herein. In this context, computing system 500 can include, for example, a processor, memory, storage, and I/O devices (e.g., monitor, keyboard, disk drive, Internet connection, etc.). However, computing system 500 can include circuitry or other specialized hardware for carrying out some or all aspects of the processes. In some operational settings, computing system 500 can be configured as a system that includes one or more units, each of which is configured to carry out some aspects of the processes either in software, hardware, or some combination thereof.

FIG. 5 depicts a computing system 500 with a number of components that can be used to perform any of the processes described, herein. The main system 502 includes a motherboard 504 having an I/O section 506, one or more central processing units (CPU) 505, and a memory section 510, which can have a flash memory card 512 related to it. The I/O section 506 can be connected to a display 514, a keyboard and/or other attendee input (not shown), a disk storage unit 516, and a media drive unit 518. The media drive unit 518 can read/write a computer-readable medium 520, which can include programs 522 and/or data. Computing system 500 can include a web browser. Moreover, it is noted that computing system 500 can be configured to include additional systems in order to fulfill various functionalities Display 514 can include a touch-screen system. In some embodiments, system 500 can be included in and/or be utilized by the various systems and/or methods described herein. As used herein, a value judgment can refer to a judgment based upon a particular set of values or on a particular value system.

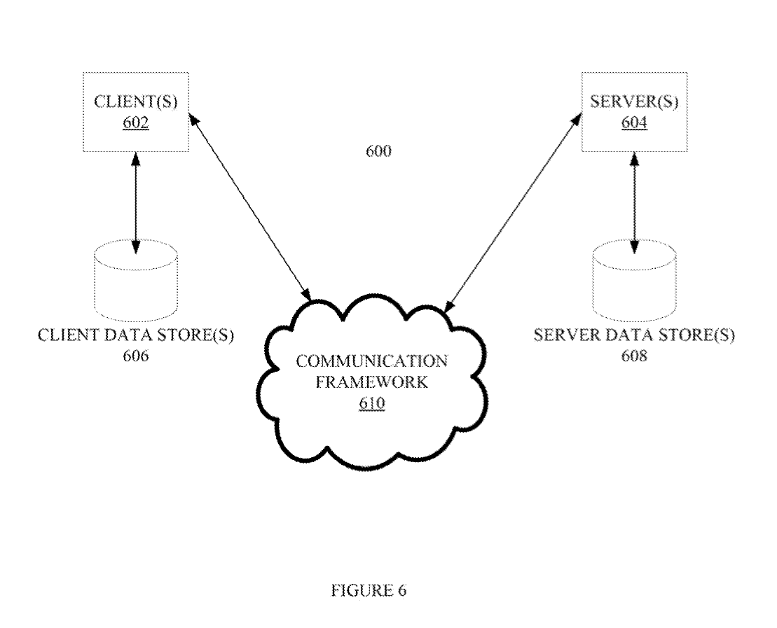

FIG. 6 is a block diagram of a sample computing environment 600 that can be utilized to implement some embodiments. The system 600 further illustrates a system that includes one or more client(s) 602. The client(s) 602 can be hardware and/or software (e.g., threads, processes, computing devices). The system 600 also includes one or more server(s) 604. The server(s) 604 can also be hardware and/or software (e.g., threads, processes, computing devices). One possible communication between a client 602 and a server 604 may be in the form of a data packet adapted to be transmitted between two or more computer processes. The system 600 includes a communication framework 610 that can be employed to facilitate communications between the client(s) 602 and the server(s) 604. The client(s) 602 are connected to one or more client data store(s) 606 that can be employed to store information local to the client(s) 602. Similarly, the server(s) 604 are connected to one or more server data store(s) 608 that can be employed to store information local to the server(s) 604.

FIG. 7 depicts an example distributed database system (DDBS) 700 that implements the multilayer caching processes provided herein, according to some embodiments. For example, DDBS 700 can implement processes 200, 300 and 400 as well as those provided in FIG. 1. DDBS 700 can be a modified version of system 100 in distributed database system environment For example, a secondary cache can be in a different node than the primary cache. A secondary cache can be stored in one or more other nodes (e.g. either completely or partially replicated in multiple nodes). In FIG. 7, each node 702A-B can include a primary cache 704A-B and a secondary cache 706A-B respectively. The primary cache 704A in node 702A can utilized a remote secondary cache such as the secondary cache 706B in node 702B (e.g. to implement process 200, 300 and/or 400 and/or any modifications thereof). It is noted that the particular multilayer caching implementation of the present figure is provide by way of example and can be modified to implement other permutations of other multilayer caching implementations (e.g. with three layers, four layers, five layers, etc.). DDBS 700 can be implemented in various distributed database and/or distributed file systems (e.g. Hadoop®, Cassandra®, OpenStack® data systems, various other ‘big data’ applications, etc.).

### CONCLUSION

Although the present embodiments have been described with reference to specific example embodiments, various modifications and changes can be made to these embodiments without departing from the broader spirit and scope of the various embodiments. For example, the various devices, modules, etc. described herein can be enabled and operated using hardware circuitry, firmware, software or any combination of hardware, firmware, and software (e.g. embodied in a machine-readable medium).

In addition, it may be appreciated that the various operations, processes, and methods disclosed herein can be embodied in a machine-readable medium and/or a machine accessible medium compatible with a data processing system (e.g., a computer system), and can be performed in any order (e.g., including using means for achieving the various operations). Accordingly, the specification and drawings are to be regarded in an illustrative rather than a restrictive sense. In some embodiments, the machine-readable medium can be a non-transitory form of machine-readable medium.

What is claimed as new and desired to be protected by Letters Patent of the United States is:

1. A method of managing a primary cache and a second cache in a multilayer cache system comprising:
maintaining a primary cache in a main memory of a computer system, wherein the primary cache is populated with a set of data from a secondary data storage system;
maintaining a secondary cache in another memory of the computer system;
selecting a subset of data from the set of data in the primary cache;
detecting a trigger event; and
populating secondary cache with the subset of data Selected from the set of data the primary cache.

2. The method of claim 1, wherein the main memory of the computer system comprises a dynamic random-access memory (DRAM) memory system.

3. The method of claim 1, wherein the other memory of the computer system comprises a flash memory system in a solid-state storage device.

4. The method of claim 1, wherein the secondary data storage system comprises a hard-disk storage system.

5. The method of claim 1, wherein the trigger event comprises an eviction stage implemented in the primary cache.

6. The method of claim 5 further comprising:
determining a probable lifespan of each memory page in the primary cache.

7. The method of claim 6 further comprising:
associating memory pages with lifespans within a specified lifespan range.

8. The method of claim 7 further comprising:
writing a set of associated memory pages with lifespans within the specified lifespan range to a block in the flash memory system.

9. The method of claim 1 further comprising:
identifying a set of contiguous memory pages in the primary cache; and
grouping the set of contiguous memory pages in the secondary cache when the contiguous memory pages are in the subset of data from the primary cache written to the secondary cache.

10. A computerized multilayer-cache system comprising:
a processor configured to execute instructions;
a memory containing instructions when executed on the processor, causes the processor to perform operations that:
maintaining a primary cache in a main memory of a computer system, wherein the primary cache is populated with a set of data from a secondary data storage system;
maintaining a secondary cache in another memory of the computer system;
selecting a subset of data from the set of data in the primary cache;
detecting a trigger event; and
populate secondary cache with the subset of data selected from the set of data in the primary cache.

11. The computerized multilayer-cache system of claim 10, wherein the main memory of the computer system comprises a dynamic random-access memory (DRAM) memory system.

12. The computerized multilayer-cache system of claim 10, wherein the other memory of the computer system comprises a flash memory system in a solid-state storage device.

13. The computerized multilayer-cache system of claim 10, wherein the other memory of the computer system comprises a flash memory system in a solid-state storage device.

14. The computerized multilayer-cache system of claim 10, wherein the trigger event comprises an eviction process implemented in the primary cache.

15. The computerized multilayer-cache system of claim 10, wherein memory containing instructions when executed on the processor, causes the processor to perform operations that:
estimate a lifespan of each memory page in the primary cache;
associate memory pages with lifespans within a specified lifespan range; and
write a set of associated memory pages with lifespans within the specified lifespan range to a block in the flash memory system.

16. The computerized multilayer-cache system of claim 15, wherein memory containing instructions when executed on the processor, causes the processor to perform operations that:
identify a set of contiguous memory pages in the primary cache; and
group the set of contiguous memory pages together in the secondary cache when the contiguous memory pages are written to the secondary cache.

17. A method of a multilayer cache system comprising:
obtaining one or memory pages from a secondary storage system;
writing the memory pages to a primary cache in a random access memory of a computing system;
identifying a subset of memory pages to write to another cache of the multilayer cache system;
evicting the memory pages from the primary cache; and
writing the subset of memory pages to the secondary cache after evicting the memory pages from the primary cache.

18. The method of claim 17,
wherein the subset of memory pages written to the other cache are selected based on a recency of use time of each memory page by an application program,
wherein a set of sequentially-accessed data detected in the primary cache is removed from the subset of memory pages written to the other cache, and
wherein the subset of memory pages are written from the primary cache to the other cache such that the other cache is not directly populated from the secondary storage system.

19. The method of claim 17, wherein the computing system comprises a distributed database system (DDBS) implementing a multilayer cache system.

20. The method of claim 19,
wherein the primary cache is located in a first node of the DDBS, and
wherein the other cache is located in a second node of the DDBS.
